(19) United States
(12) Patent Application Publication
(10) Pub. No.: US 2026/0013348 A1
(43) Pub. Date: Jan. 8, 2026

(54) DISPLAY DEVICE, METHOD FOR REPAIRING THE DISPLAY DEVICE, AND ELECTRONIC DEVICE INCLUDING THE DISPLAY DEVICE

(71) Applicant: Samsung Display Co., LTD., Yongin-si (KR)

(72) Inventors: Young Woo PARK, Yongin-si (KR); Jin A LEE, Yongin-si (KR); Wan Soon IM, Yongin-si (KR); Taek Ju JUNG, Yongin-si (KR); Seong Baik CHU, Yongin-si (KR)

(21) Appl. No.: 19/037,420

(22) Filed: Jan. 27, 2025

(30) Foreign Application Priority Data
Jul. 5, 2024 (KR) 10-2024-0088946

(51) Int. Cl. H10K 59/131; H10K 59/12; H10K 59/124; H10K 71/00

(52) U.S. Cl. CPC H10K 59/131; H10K 59/1201; H10K 59/124; H10K 71/861

(57) ABSTRACT

A display device includes an inorganic insulating layer array including a plurality of inorganic insulating layers sequentially laminated in a thickness direction, a data pad disposed on the inorganic insulating layer array, a data driving chip disposed on the data pad and connected to the data pad, an adhesive layer disposed between the data driving chip and the inorganic insulating layer array, a lower data extension wiring interposed between adjacent inorganic insulating layers and connected to the data pad, an upper data extension wiring disposed on the inorganic insulating layer array and connected to the lower data extension wiring, an organic insulating layer array disposed on the inorganic insulating layer array, covering the upper data extension wiring, and including a plurality of organic insulating layers sequentially laminated in the thickness direction and a cladding electrode covering a boundary between the organic insulating layer array and the inorganic insulating layer array.

The application claims priority to Korean Patent Application No. 10-2024-0088946, filed on Jul. 5, 2024, and all the benefits accruing therefrom under 35 U.S.C. § 119, the content of which in its entirety is herein incorporated by reference.

### BACKGROUND

### 1. Field

The present invention relates to a display device and more particularly, to a display device, a method for repairing the display device, and an electronic device including the display device.

### 2. Discussion of Related Art

A display device is a device that displays an image. The display device includes various types of wiring. For example, the display device may include a first insulating layer, a second insulating layer disposed on the first insulating layer, a first wiring interposed between the first insulating layer and the second insulating layer, and a second wiring disposed on the second insulating layer.

For a variety of reasons, the display device may experience an insulating layer peeling off within the display device. For example, the second insulating layer may be peeled off. In this case, the second wiring disposed on the second insulating layer may also be removed along with the second insulating layer being peeled off. As a result, a defect may occur in the display device.

### SUMMARY

The present invention provides a display device whose reliability can be improved by preventing defects from occurring.

The present invention also provides a method for repairing the display device.

A display device, according to an embodiment, may include an inorganic insulating layer array including a plurality of inorganic insulating layers sequentially laminated in a thickness direction, a data pad disposed on the inorganic insulating layer array, a data driving chip disposed on the data pad and connected to the data pad, an adhesive layer disposed between the data driving chip and the inorganic insulating layer array, a lower data extension wiring interposed between two adjacent inorganic insulating layers among the plurality of inorganic insulating layers included in the inorganic insulating layer array and connected to the data pad, an upper data extension wiring disposed on the inorganic insulating layer array and connected to the lower data extension wiring, an organic insulating layer array disposed on the inorganic insulating layer array, covering the upper data extension wiring, and including a plurality of organic insulating layers sequentially laminated in the thickness direction and a cladding electrode covering a boundary between the organic insulating layer array and the inorganic insulating layer array between the data pad and the upper data extension wiring.

In an embodiment, the organic insulating layer array may include a first via insulating layer disposed on the inorganic insulating layer array and a second via insulating layer disposed on the first via insulating layer.

In an embodiment, the cladding disposed between the data pad and the upper data extension wiring may cover a side surface of the first via insulating layer.

In an embodiment, at least a portion of the cladding electrode may be interposed between the first via insulating layer and the second via insulating layer.

In an embodiment, at least a portion of the cladding electrode may cover an upper surface of the inorganic insulating layer array adjacent to the side surface of the first via insulating layer.

In an embodiment, the cladding electrode disposed between the data pad and the upper data extension wiring may be interposed between the side surface of the first via insulating layer and the adhesive layer.

In an embodiment, the cladding electrode disposed between the data pad and the upper data extension wiring may expose a side surface of the second via insulating layer.

In an embodiment, the display device may further include an additional cladding electrode disposed on the second via insulating layer and completely covering the side surface of the second via insulating layer that is exposed and that is not covered by the cladding electrode between the data pad and the upper data extension wiring.

In an embodiment, the additional cladding electrode may be in contact with the cladding electrode.

In an embodiment, the additional cladding electrode may include an opening exposing a portion of an upper surface of the second via insulating layer.

In an embodiment, the data pad may include a first data pad and a second data pad spaced apart from the first data pad. The lower data extension wiring may include a first lower data extension wiring connected to the first data pad and a second lower data extension wiring connected to the second data pad. The upper data extension wiring may include a first upper data extension wiring connected to the first lower data extension wiring and a second upper data extension wiring connected to the second lower data extension wiring.

In an embodiment, the first upper data extension wiring may be interposed between the inorganic insulating layer array and the first via insulating layer, wherein the second upper data extension wiring may be interposed between the first via insulating layer and the second via insulating layer.

In an embodiment, the display device may further include a data bridge electrode interposed between the inorganic insulating layer array and the first via insulating layer, and electrically contacting the second lower data extension wiring and the second upper data extension wiring.

In an embodiment, the cladding electrode may further include a protrusion overlapping the first upper data extension wiring when viewed on a plane.

In an embodiment, the protrusion may be disposed on the same layer as the second upper data extension wiring.

In an embodiment, the protrusion may be spaced apart from the second upper data extension wiring.

In an embodiment, the cladding electrode may overlap a portion of the lower data extension wiring when viewed on a plane.

In an embodiment, the display device may further include a voltage transmission wiring disposed on the inorganic insulating layer array and connected to the cladding electrode.

In an embodiment, a level of a voltage applied to the voltage transmission wiring may be a level between a high level and a low level of a data voltage applied to the lower data extension wiring.

In an embodiment, a method for repairing a display device may include removing the data driving chip by applying an external force to the data driving chip.

### BRIEF DESCRIPTION OF THE DRAWINGS

The accompanying drawings, which are included to provide a further understanding of the inventive and are incorporated in and constitute a part of this specification, illustrate embodiments of the invention, and, together with the description, serve to explain principles of the invention.

FIG. 1 is a schematic diagram for explaining a display device, according to an embodiment.

FIG. 2 is a schematic diagram for explaining a pixel included in the display device of FIG. 1, according to an embodiment.

FIG. 3 is a schematic diagram for explaining a pixel included in the display device of FIG. 1, according to an embodiment.

FIG. 4 is a plan view of a display panel for explaining a display panel included in the display device of FIG. 1, according to an embodiment.

FIG. 5 is a schematic diagram for explaining an embodiment of a cladding electrode included in the display panel of FIG. 4, according to an embodiment.

FIG. 6 is a schematic diagram for explaining an embodiment of a cladding electrode included in the display panel of FIG. 4, according to an embodiment.

FIG. 7 is a schematic diagram for explaining an embodiment of a cladding electrode included in the display panel of FIG. 4, according to an embodiment.

FIG. 8 is a schematic diagram for explaining an embodiment of a cladding electrode included in the display panel of FIG. 4, according to an embodiment.

FIG. 9 is a schematic diagram for explaining an embodiment of a cladding electrode included in the display panel of FIG. 4, according to an embodiment.

FIG. 10 is a schematic diagram for explaining an embodiment of a cladding electrode included in the display panel of FIG. 4, according to an embodiment.

FIG. 11 is a schematic diagram for explaining an embodiment of a cladding electrode included in the display panel of FIG. 4, according to an embodiment.

FIG. 12 is a diagram for explaining a method for repairing a display device, according to an embodiment.

FIG. 13 is a diagram for explaining a method for repairing a display device, according to an embodiment.

FIG. 14 is a diagram for explaining one modified example of the cladding electrode included in the display panel of FIG. 4, according to an embodiment.

FIG. 15 is a diagram for explaining one modified example of the cladding electrode included in the display panel of FIG. 4, according to an embodiment.

FIG. 16 is a diagram for explaining one modified example of the cladding electrode included in the display panel of FIG. 4, according to an embodiment.

FIG. 17 is a diagram for explaining another modified example of the cladding electrode included in the display panel of FIG. 4, according to an embodiment.

FIG. 18 is a diagram for explaining another modified example of the cladding electrode included in the display panel of FIG. 4, according to an embodiment.

FIG. 19 is a diagram for explaining another modified example of the cladding electrode included in the display panel of FIG. 4, according to an embodiment.

FIG. 20 is a plan view for explaining still another modified example of the cladding electrode included in the display panel of FIG. 4, according to an embodiment.

FIG. 21 is a block diagram of an electronic device according to an embodiment.

FIG. 22 shows schematic views of various embodiments of an electronic device.

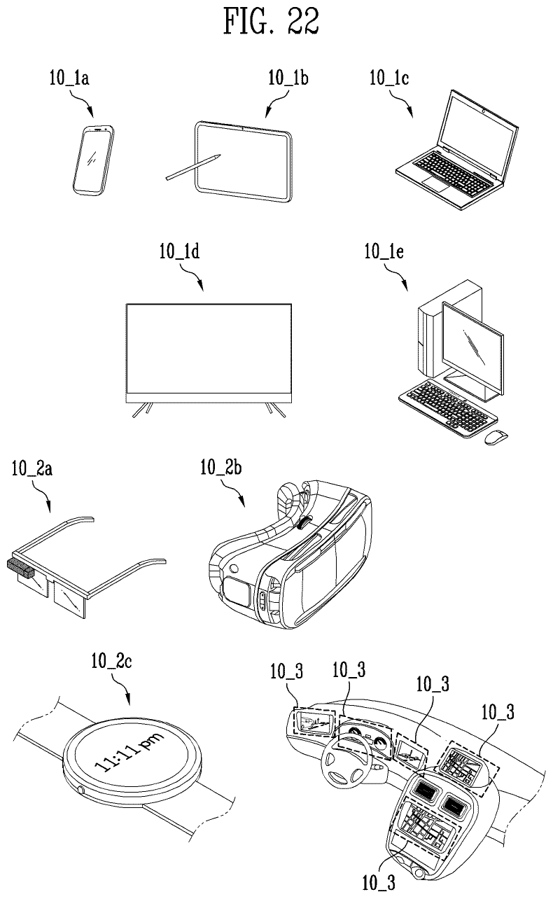

### DETAILED DESCRIPTION

Hereinafter, preferred embodiments will be described in detail with reference to the accompanying drawings. It should be noted that in the following description, only parts necessary for understanding the operation are described, and descriptions of other parts will be omitted in order not to obscure the subject matter of the present disclosure. In addition, the invention is not limited to the embodiments described herein and may be embodied in other forms. However, the embodiments described herein are provided to explain in detail so that those skilled in the art can easily practice the technical spirit of the invention.

Throughout the specification, when a first part is said to be connected or coupled to a second part, this includes not only a case where the first part and the second part are directly connected or coupled, but also a case where they are indirectly connected or coupled by another element interposed between them. Terms used herein are for describing specific embodiments and are not intended to limit the present disclosure. Throughout the specification, when a part includes a certain component, unless the context clearly indicates otherwise, this means that it may further include other components rather than excluding other components. At least one of X, Y, and Z, and at least one selected from the group consisting of X, Y, and Z may be construed as one X, one Y, one Z, or any combination of two or more of X, Y, and Z (for example, XYZ, XYY, YZ and ZZ). As used herein, the term “and/or” may include any combination of one or more of the corresponding elements.

Although the terms “first”, “second”, etc. may be used herein to describe various elements, these elements should not be limited by these terms. These terms are only used to distinguish one element from another element. Thus, a first element discussed below could be termed a second element without departing from the scope of the present disclosure.

Spatially relative terms such as “beneath”, “below”, “under”, “lower”, “above”, “upper”, “over”, and the like may be used herein for descriptive purposes. By doing so, the relationship between one element or feature and another element(s) or feature(s) is explained, as shown in the drawings. Spatially relative terms are intended to include other directions in use, operation, and/or manufacture, in addition to the directions depicted in the drawings. For example, when the device shown in the drawings is turned upside down, elements depicted as being “below” or “beneath” other elements or features are positioned “above” the other elements or features. Thus, in an embodiment, the term “below” may include both directions “above” and “below”. In addition, the device may be oriented in other directions (for example, rotated 90 degrees or in other directions). Accordingly, the spatially relative terms used herein may be interpreted accordingly.

Various embodiments are described with reference to the drawings where ideal embodiments are schematically illustrated. Accordingly, it will be expected that their shapes may vary depending, for example, on tolerances and/or manufacturing techniques. Accordingly, the embodiments disclosed herein should not be construed as being limited to the specific shapes shown in the drawings. For example, it should be interpreted to include changes in shape that occur as a result of manufacturing. As such, the shapes shown in the drawings may not illustrate the actual shapes of areas of the device, and the embodiments may not be limited thereto.

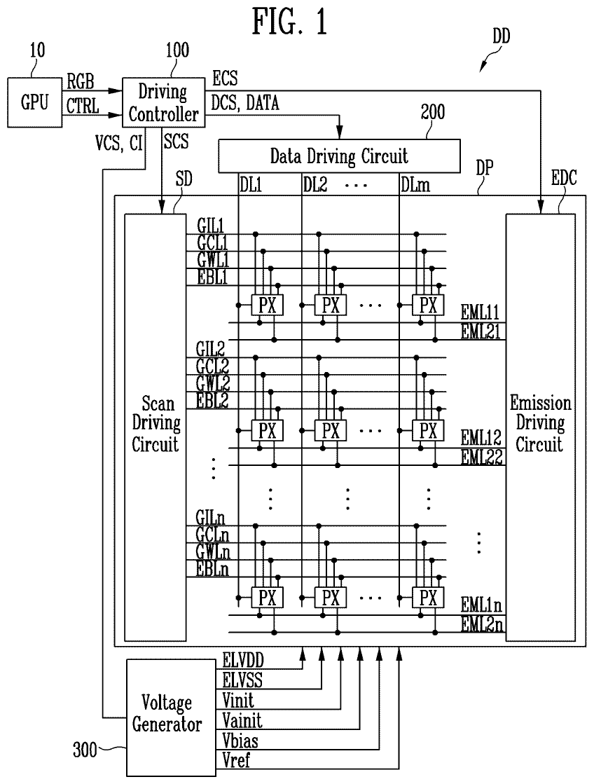

FIG. 1 is a diagram for explaining a display device, according to an embodiment.

In an embodiment and referring to FIG. 1, a display device DD may include a host processor 10, a display panel DP, a driving controller 100, a data driving circuit 200, and a voltage generator 300.

In an embodiment, the host processor 10 may be a graphics processing unit (GPU). The host processor 10 may provide an image signal RGB and a control signal CTRL to the driving controller 100 and may control a display operation of the display panel DP through the image signal RGB and the control signal CTRL.

In an embodiment, the display panel DP, which may include various types of known display panels capable of self-light emitting, such as an organic light emitting display panel, a quantum dot light emitting display panel, a Micro LED display panel, or the like may be applied without limitation.

In an embodiment, the driving controller 100 may receive the image signal RGB and the control signal CTRL and may generate an image data signal DATA in which the data format of the image signal RGB is converted to suit the interface specifications with the data driving circuit 200. The driving controller 100 may output a scan control signal SCS, a data control signal DCS, an emission driving control signal ECS, a voltage control signal VCS, and a compensation signal CI.

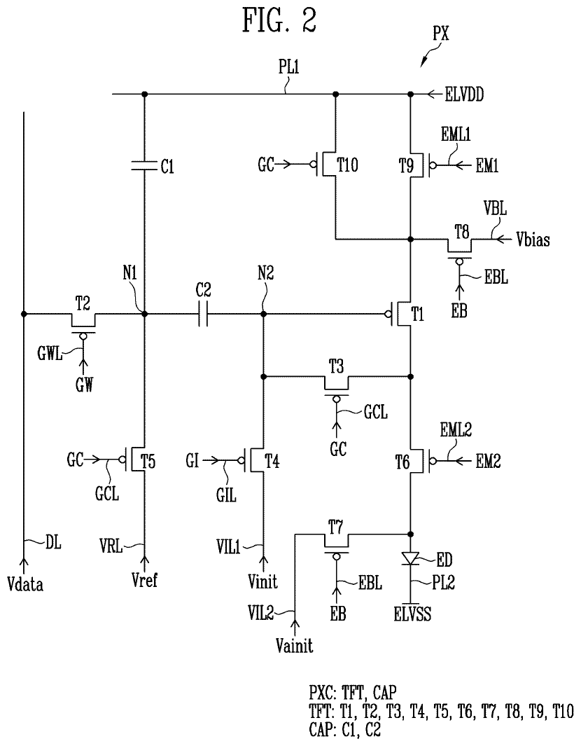

In an embodiment, the data driving circuit 200 may receive the data control signal DCS and the image data signal DATA from the driving controller 100. The data driving circuit 200 may convert the image data signal DATA into a data voltage Vdata (see FIG. 2) and output the data voltage Vdata to a plurality of data lines DL1 to DLm. The data voltage Vdata may be an analog voltage corresponding to a grayscale value of the image data signal DATA.

In an embodiment, the voltage generator 300 may receive the voltage control signal VCS and the compensation signal CI from the driving controller 100. The voltage generator 300 may generate voltages required for the operation of the display panel DP based on the voltage control signal VCS and the compensation signal CI. The voltage generator 300 may provide these voltages to the display panel DP. In an embodiment, the voltages may include a first driving voltage ELVDD, a second driving voltage ELVSS, a first initialization voltage Vinit, a second initialization voltage Vainit, a bias voltage Vbias, and a reference voltage Vref.

In an embodiment, the display panel DP may include scan lines GIL1 to GILn, GCL1 to GCLn, GWL1 to GWLn, and EBL1 to EBLn, emission control lines EML11 to EML1n and EML21 to EML2n, data lines DL1 to DLm, and pixels PX. In an embodiment, the display panel DP may further include a scan driving circuit SD and an emission driving circuit EDC.

In an embodiment, the scan driving circuit SD may be disposed on one side of the display panel DP and the scan lines GIL1 to GILn, GCL1 to GCLn, GWL1 to GWLn, and EBL1 to EBLn may extend in a row direction.

In an embodiment, the emission driving circuit EDC may be disposed on the other side of the display panel DP and the emission control lines EML11 to EML1n and EML21 to EML2n may extend in the row direction.

In an embodiment, the scan lines GIL1 to GILn, GCL1 to GCLn, GWL1 to GWLn, and EBL1 to EBLn and the emission control lines EML11 to EML1n and EML21 to EML2n may be arranged in a column direction intersecting the row direction.

In an embodiment, the data lines DL1 to DLm may extend in the column direction and may be arranged in the row direction.

In an embodiment as shown in FIG. 1, the scan driving circuit SD and the emission driving circuit EDC may be arranged to face each other with the pixels PX interposed therebetween, but the invention is not limited thereto. For example, the scan driving circuit SD and the emission driving circuit EDC may be arranged to be disposed adjacent to one side or the other side of the display panel DP. In an embodiment, the scan driving circuit SD and the emission driving circuit EDC may be configured as a single circuit.

In an embodiment, the pixels PX may be connected to the scan lines GIL1 to GILn, GCL1 to GCLn, GWL1 to GWLn, and EBL1 to EBLn, the emission control lines EML11 to EML1n and EML21 to EML2n, and the data lines DL1 to DLm. Each of the pixels PX may be connected to four scan lines, two emission control lines, and one data line. However, this is only an example, and the number of lines connected to each of the pixels PX is not limited thereto.

In an embodiment, the scan lines GIL1 to GILn, GCL1 to GCLn, GWL1 to GWLn, and EBL1 to EBLn may include initialization scan lines GIL1 to GILn, compensation scan lines GCL1 to GCLn, scan signal lines GWL1 to GWLn, and emission initialization signal lines EBL1 to EBLn.

In an embodiment, the emission control lines EML11 to EML1n and EML21 to EML2n may include first emission control lines EML11 to EML1n and second emission control lines EML21 to EML2n.

In an embodiment, each of the pixels PX may include a light emitting diode ED (see FIG. 2) and a pixel circuit PXC (see FIG. 2) that controls the light emitting of the light emitting diode ED.

In an embodiment, the light emitting diode ED of each of the pixels PX may generate light of a different color. For example, the pixels PX may include red pixels that generate red light, green pixels that generate green light, and blue pixels that generate blue light. In an embodiment, the light emitting diode of the red pixel, the light emitting diode of the green pixel, and the light emitting diode of the blue pixel may be composed of different materials.

In an embodiment, the pixel circuit PXC may include at least one transistor and at least one capacitor. In an embodiment, the scan driving circuit SD and the emission driving circuit EDC may include transistors formed through the same process as the transistors of the pixel circuit PXC.

In an embodiment, each of the pixels PX may receive the first driving voltage ELVDD, the second driving voltage ELVSS, the first initialization voltage Vinit, the second initialization voltage Vainit, the bias voltage Vbias, and the reference voltage Vref from the voltage generator 300.

In an embodiment, the scan driving circuit SD may receive the scan control signal SCS from the driving controller 100. The scan driving circuit SD may output scan signals to the scan lines GIL1 to GILn, GCL1 to GCLn, GWL1 to GWLn, and EBL1 to EBLn in response to the scan control signal SCS.

In an embodiment, the emission driving circuit EDC may output emission signals to the emission control lines EML11 to EML1n and EML21 to EML2n in response to the emission driving control signal ECS from the driving controller 100.

In an embodiment, the driving controller 100 may determine a driving frequency and control the data driving circuit 200, the scan driving circuit SD, and the emission driving circuit EDC according to the determined driving frequency.

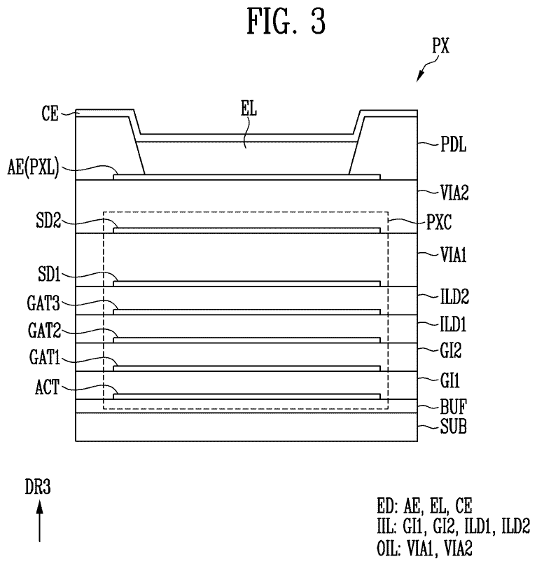

FIGS. 2 and 3 are diagrams for explaining a pixel included in the display device of FIG. 1, according to an embodiment.

In an embodiment and referring to FIG. 2, a pixel PX may include a pixel circuit PXC and a light emitting diode ED.

In an embodiment, the pixel circuit PXC may include transistors TFT and capacitors CAP. In an embodiment, the transistors TFT may include first to tenth transistors T1, T2, T3, T4, T5, T6, T7, T8, T9, and T10, respectively, and the capacitors CAP may include first and second capacitors C1 and C2, respectively. However, this is only an example, and the number of transistors and the number of capacitors included in the pixel circuit PXC may be variously changed.

In an embodiment, each of the transistors T1, T2, T3, T4, T5, T6, T7, T8, T9, and T10 may be a P-type transistor including a low-temperature polycrystalline silicon (LTPS) semiconductor layer. However, this is only an example, and at least one of the transistors T1, T2, T3, T4, T5, T6, T7, T8, T9, and T10 may be a P-type transistor, and the rest may be N-type transistors having an oxide semiconductor as a semiconductor layer.

In an embodiment, scan lines GIL, GCL, GWL, and EBL may transmit scan signals GI, GC, GW, and EB. The scan lines GIL, GCL, GWL, and EBL may include an initialization scan line GIL, a compensation scan line GCL, a scan signal line GWL, and an emission initialization signal line EBL. The initialization scan line GIL may be one of initialization scan lines GIL1 to GILn (see FIG. 1). The compensation scan line GCL may be one of compensation scan lines GCL1 to GCLn (see FIG. 1). The scan signal line GWL may be one of scan signal lines GWL1 to GWLn (see FIG. 1). The emission initialization signal line EBL may be one of emission initialization signal lines EBL1 to EBLn (see FIG. 1).

In an embodiment, emission control lines EML1 and EML2 may transmit emission signals EM1 and EM2 and may include a first emission control line EML1 and a second emission control line EML2. The first emission control line EML1 may be one of first emission control lines EML11 to EML1n (see FIG. 1) and the second emission control line EML2 may be one of second emission control lines EML21 to EML2n (see FIG. 1).

In an embodiment, a data line DL may transmit the data voltage Vdata, where Vdata may have a voltage level corresponding to the image signal RGB input to the display device DD (see FIG. 1). A first voltage line PL1 may transmit the first driving voltage ELVDD. A second voltage line PL2 may transmit the second driving voltage ELVSS. In an embodiment, the first driving voltage ELVDD may have a voltage level higher than that of the second driving voltage ELVSS. A first initialization voltage line VIL1 may transmit the first initialization voltage Vinit. A second initialization voltage line VIL2 may transmit the second initialization voltage Vainit. A bias voltage line VBL may transmit the bias voltage Vbias. A reference voltage line VRL may transmit the reference voltage Vref.

In an embodiment, a first capacitor C1 may be connected between the first voltage line PL1 and a first node N1 and a second capacitor C2 may be connected between the first node N1 and a second node N2.

In an embodiment, the light emitting diode ED may include an anode electrode connected to the first voltage line PL1 via the ninth transistor T9, the first transistor T1, and the sixth transistor T6 and a cathode electrode connected to the second voltage line PL2.

In an embodiment, the first transistor Tl may include a first terminal connected to the first voltage line PL1 via the ninth transistor T9, a second terminal connected to the anode electrode of the light emitting diode ED via the sixth transistor T6, and a gate electrode connected to the second node N2. The first transistor Tl may be referred to as a driving transistor.

In an embodiment, the second transistor T2 may include a first terminal connected to the data line DL, a second terminal connected to the first node N1, and a gate electrode receiving a first scan signal GW.

In an embodiment, the third transistor T3 may include a first terminal connected to the second node N2, a second terminal connected to the second terminal of the first transistor T1, and a gate electrode receiving a compensation scan signal GC.

In an embodiment, the fourth transistor T4 may include a first terminal connected to the second node N2, a second terminal connected to the first initialization voltage line VIL1, and a gate electrode receiving an initialization scan signal GI.

In an embodiment, the fifth transistor T5 may include a first terminal connected to the first node N1, a second terminal connected to the reference voltage line VRL, and a gate electrode receiving the compensation scan signal GC.

In an embodiment, the sixth transistor T6 may include a first terminal connected to the second terminal of the first transistor T1, a second terminal connected to the anode electrode of the light emitting diode ED, and a gate electrode receiving a second emission signal EM2.

In an embodiment, the seventh transistor T7 may include a first terminal connected to the second initialization voltage line VIL2, a second terminal connected to the anode electrode of the light emitting diode ED, and a gate electrode receiving a second scan signal EB.

In an embodiment, the eighth transistor T8 may include a first terminal connected to the first terminal of the first transistor T1, a second terminal connected to the bias voltage line VBL, and a gate electrode receiving the second scan signal EB.

In an embodiment, the ninth transistor T9 may include a first terminal connected to the first voltage line PL1, a second terminal connected to the first terminal of the first transistor T1, and a gate electrode receiving a first emission signal EM1.

In an embodiment, the tenth transistor T10 may include a first terminal connected to the first voltage line PL1, a second terminal connected to the first terminal of the first transistor T1, and a gate electrode receiving the compensation scan signal GC.

In an embodiment and referring to FIG. 3, the pixel PX may include a substrate SUB, a buffer layer BUF, an active layer ACT, a first gate insulating layer GI1, a first gate conductive layer GAT1, a second gate insulating layer GI2, a second gate conductive layer GAT2, a first interlayer insulating layer ILD1, a third gate conductive layer GAT3, a second interlayer insulating layer ILD2, a first SD conductive layer SD1, a first via insulating layer VIA1, a second SD conductive layer SD2, a second via insulating layer VIA2, an anode electrode AE, an organic light emitting layer EL, and a cathode electrode CE sequentially laminated along a third direction DR3 (thickness direction).

In an embodiment, the substrate SUB may be made of various materials such as glass, polymer, metal, or the like and depending on a product to be applied, the substrate SUB may be rigid or flexible.

In an embodiment, the buffer layer BUF may include an inorganic insulating material and may serve to prevent diffusion of impurities. In another embodiment, the buffer layer BUF may be omitted.

In an embodiment, the active layer ACT may include a semiconductor material. For example, the active layer ACT may include a polysilicon semiconductor. The active layer ACT may define channels and terminals of the transistors TFT included in the pixel circuit PXC.

In an embodiment, each of the first gate conductive layer GAT1, the second gate conductive layer GAT2, the third gate conductive layer GAT3, the first SD conductive layer SD1, and the second SD conductive layer SD2 may independently be composed of a single layer or multiple layers, and may be composed of a known conductive material such as gold (Au), silver (Ag), aluminum (Al), molybdenum (Mo), chromium (Cr), titanium (Ti), nickel (Ni), neodymium (Nd), copper (Cu), or platinum (Pt).

In an embodiment, the first gate insulating layer GI1, the second gate insulating layer GI2, the first interlayer insulating layer ILD1, and the second interlayer insulating layer ILD2 sequentially laminated may be referred to as an inorganic insulating layer array IIL. The first gate insulating layer GI1, the second gate insulating layer GI2, the first interlayer insulating layer ILD1, and the second interlayer insulating layer ILD2 may include an inorganic insulating material. For example, the first gate insulating layer GI1, the second gate insulating layer GI2, the first interlayer insulating layer ILD1, and the second interlayer insulating layer ILD2 may include silicon oxide, silicon nitride, silicon oxynitride, or the like.

In an embodiment, each of the first gate conductive layer GATI, the second gate conductive layer GAT2, the third gate conductive layer GAT3, the first SD conductive layer SD1, and the second SD conductive layer SD2 may include various conductive patterns. These conductive patterns may constitute the transistors TFT and the capacitors CAP included in the pixel circuit PXC.

In an embodiment, the first via insulating layer VIA1 and second via insulating layer VIA2 sequentially laminated may be referred to as an organic insulating layer array OIL, where the first via insulating layer VIA1 and the second via insulating layer VIA2 may include an organic insulating material. For example, the first via insulating layer VIA1 and the second via insulating layer VIA2 may include an epoxy resin, a phenolic resin, a polyamide resin, a polyimide resin, or the like.

In an embodiment, the insulating layers constituting the inorganic insulating layer array IIL and the insulating layers constituting the organic insulating layer array OIL may be interposed to electrically isolate the first gate conductive layer GAT1, the second gate conductive layer GAT2, the third gate conductive layer GAT3, the first SD conductive layer SD1, and the second SD conductive layer SD2. In this case, if necessary, conductive patterns may be connected to each other through through-holes formed in the insulating layers GI1, GI2, ILD1, ILD2, VIA1, and VIA2.

In an embodiment, the anode electrode AE, the organic light emitting layer EL, and the cathode electrode CE may form the light emitting diode ED.

In an embodiment, the anode electrode AE may be disposed on the second via insulating layer VIA2 and may be connected to at least one conductive pattern (for example, a conductive pattern connected to the second terminal of the sixth transistor T6 of FIG. 2) among the conductive patterns constituting the pixel circuit PXC through a through-hole penetrating one or more of the insulating layers constituting the inorganic insulating layer array IIL and the insulating layers constituting the organic insulating layer array OIL.

In an embodiment, the anode electrode AE may be an electrode pattern implemented as a pixel electrode layer PXL.

In an embodiment, a pixel defining layer PDL may be disposed on the anode electrode AE and the second via insulating layer VIA2. The pixel defining layer PDL may include a pixel opening that exposes a portion of the anode electrode AE, where the pixel defining layer PDL may include an insulating material. For example, the pixel defining layer PDL may include an organic insulating material and/or an inorganic insulating material.

In an embodiment, the organic light emitting layer EL may be disposed on the anode electrode AE within the pixel opening of the pixel defining layer PDL and may include an organic light emitting material.

In an embodiment, the cathode electrode CE may be disposed on the pixel defining layer PDL and the organic light emitting layer EL and may be connected to the second voltage line PL2 and receive the second driving voltage ELVSS.

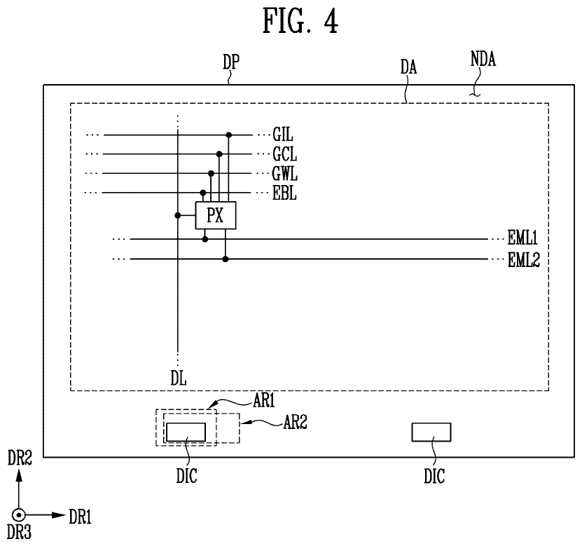

FIG. 4 is a plan view for explaining a display panel included in the display device of FIG. 1, according to an embodiment.

In an embodiment and referring to FIG. 4, the display panel DP may include a display area DA and a non-display area NDA.

In an embodiment, the pixel PX, the initialization scan line GIL, the compensation scan line GCL, the scan signal line GWL, the emission initialization signal line EBL, the first emission control line EML1, the second emission control line EML2, and the data line DL may be disposed in the display area DA. The initialization scan line GIL, the compensation scan line GCL, the scan signal line GWL, the emission initialization signal line EBL, the first emission control line EML1, the second emission control line EML2, and the data line DL may be connected to the pixel PX.

In an embodiment, the initialization scan line GIL, the compensation scan line GCL, the scan signal line GWL, the emission initialization signal line EBL, the first emission control line EML1, and the second emission control line EML2 may extend in a first direction DR1. The data line DL may extend in a second direction DR2 intersecting the first direction DR1.

In an embodiment and as shown in FIG. 4, for convenience of description, each of the pixel PX, the initialization scan line GIL, the compensation scan line GCL, the scan signal line GWL, the emission initialization signal line EBL, the first emission control line EML1, the second emission control line EML2, and the data line DL is shown as one, but, in another embodiment, each of these components may be provided in multiples in the display area DA.

In an embodiment, various components for generating and transmitting voltages (or signals) to components disposed in the display area DA may be disposed in the non-display area NDA. For example, the scan driving circuit SD and the emission driving circuit EDC described with reference to FIG. 1 may be disposed in the non-display area NDA.

In an embodiment, the driving controller 100, the data driving circuit 200, and the voltage generator 300 may be implemented as a separate circuit board (or circuit chip) separate from the display panel DP. This circuit board (or circuit chip) may be connected to wirings disposed in the non-display area NDA.

In an embodiment, the data driving circuit 200 may be implemented as a data driving chip DIC which may be disposed in the non-display area NDA of the display panel DP. The data driving chip DIC may be connected to a data extension wiring disposed in the non-display area NDA of the display panel DP, where the data extension wiring may be connected to the data line DL disposed in the display area DA of the display panel DP.

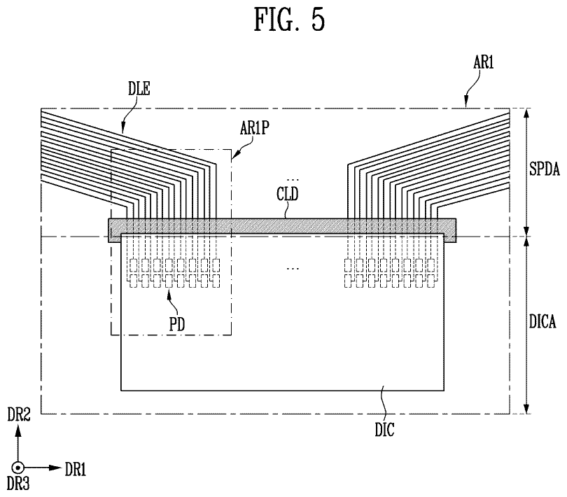

FIGS. 5 to 11 are diagrams for explaining an embodiment of a cladding electrode included in the display panel of FIG. 4.

FIG. 5 is an enlarged plan view of an area AR1 in FIG. 4, according to an embodiment.

Referring to FIG. 5, among the non-display area NDA, an embodiment of a driving chip attachment area DICA and a wiring extension area SPDA disposed around the data driving chip DIC are shown.

In an embodiment, in the driving chip attachment area DICA, the display panel DP may include a data pad PD. The data driving chip DIC may be disposed on the data pad DP and connected to the data pad PD. Accordingly, the data pad DP may receive the data voltage Vdata provided from the data driving chip DIC.

In an embodiment, in the driving chip attachment area DICA and the wiring extension area SPDA, the display panel DP may include a data extension wiring DLE. The data extension wiring DLE may be connected to the data pad PD and may serve to transmit the data voltage Vdata.

In an embodiment, in the driving chip attachment area DICA, the data extension wiring DLE may extend in the second direction DR2 and in the wiring extension area SPDA, the data extension wiring DLE may extend in a direction intersecting the second direction DR2.

In an embodiment, the data pad PD and data extension wiring DLE may be provided in multiples. In this case, data extension wirings DLE may be connected to data pads DP in a one-to-one correspondence, where the data extension wirings DLE may extend in various directions intersecting the second direction DR2 in the wiring extension area SPDA.

In an embodiment, the data extension wirings DLE may extend in a direction toward the display area DA in the non-display area NDA between the wiring extension area SPDA and the display area DA and may be connected to data lines DL disposed in the display area DA.

In an embodiment, the data extension wirings DLE may be connected to the data lines DL in a one-to-one correspondence. In another embodiment, among the data extension wirings DLE, one data extension wiring DLE may be connected to two or more data lines DL. In this case, between one data extension wiring DLE and two or more data lines DL, a demultiplexer circuit may be further provided to sequentially output the data voltage Vdata transmitted by the data extension wiring DLE to two or more data lines DL.

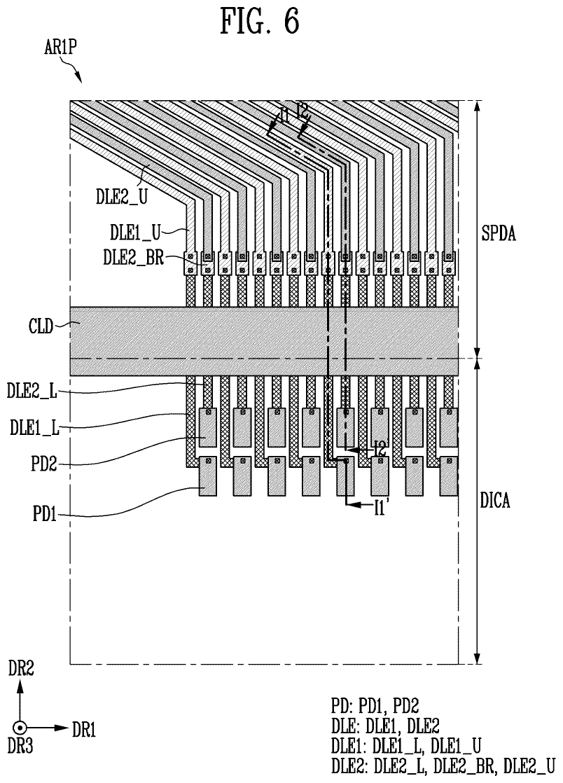

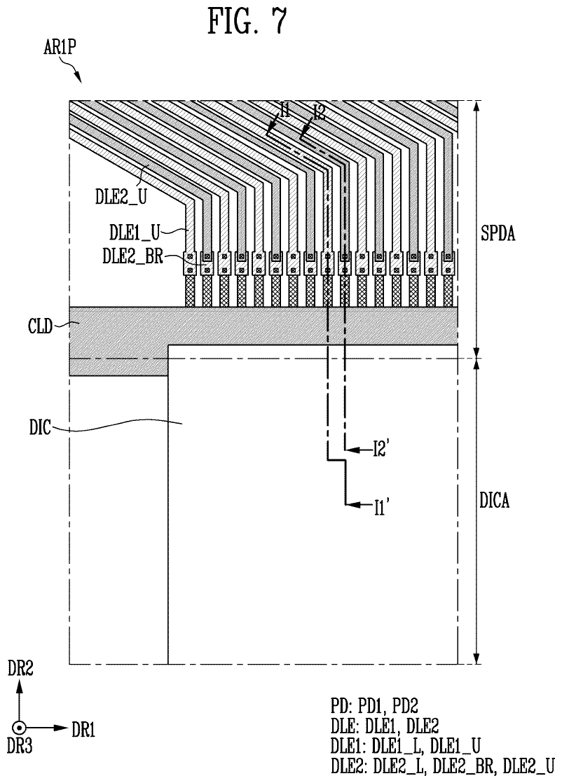

FIGS. 6 and 7 are enlarged plan views of an area AR1P in FIG. 5, according to an embodiment. In FIG. 6, the data driving chip DIC is omitted for convenience of description.

In an embodiment and referring to FIGS. 6 and 7, the data pad PD may include a first data pad PD1 and a second data pad PD2. The data extension wiring DLE may include a first data extension wiring DLE1 and a second data extension wiring DLE2.

In an embodiment, the first data pad PD1 may be spaced apart from the second data pad PD2. For example, the second data pad PD2 may be spaced apart from the first data pad PD1 in the second direction DR2.

In an embodiment, the first data extension wiring DLE1 may be connected to the first data pad PD1 and the second data extension wiring DLE2 may be connected to the second data pad PD2. The first data extension wiring DLE1 and the second data extension wiring DLE2 may not physically contact each other.

In an embodiment, the first data extension wiring DLE1 may include a first lower data extension wiring DLE1_L and a first upper data extension wiring DLE1_U, where the first lower data extension wiring DLE1_L may be connected to the first data pad PD1. The first lower data extension wiring DLE1_L may extend in the second direction DR2. The first upper data extension wiring DLE1_U may be connected to the first lower data extension wiring DLE1_L and the first upper data extension wiring DLE1_U may extend in a direction intersecting the second direction DR2.

In an embodiment, the second data extension wiring DLE2 may include a second lower data extension wiring DLE2_L, a second upper data extension wiring DLE2_U, and a data bridge electrode DLE2_BR. The second lower data extension wiring DLE2_L may be connected to the second data pad PD2 and may extend in the second direction DR2. The data bridge electrode DLE2_BR may be connected to the second lower data extension wiring DLE2_L. The second upper data extension wiring DLE2_U may be connected to the data bridge electrode DLE2_BR and may extend in a direction intersecting the second direction DR2.

In an embodiment, the first data pad PD1 and the first data extension wiring DLE1 may be provided in multiples. In this case, first data extension wirings DLE1 may be connected to first data pads PD1 in a one-to-one correspondence.

In an embodiment, the second data pad PD2 and the second data extension wiring DLE2 may be provided in multiples. In this case, second data extension wirings DLE2 may be connected to second data pads PD2 in a one-to-one correspondence.

In an embodiment, a cladding electrode CLD may be disposed between first and second upper data connection wirings DLE1_P2 and DLE2_P2, respectively, and first and second data pads PD1 and PD2, respectively. The cladding electrode CLD may be disposed to overlap the boundary between the driving chip attachment area DICA and the wiring extension area SPDA when viewed on a plane. The cladding electrode CLD may overlap portions of the first and second lower data extension wirings DLE1_L and DLE2_L when viewed on a plane. The cladding electrode CLD may overlap a portion of the data driving chip DIC when viewed on a plane.

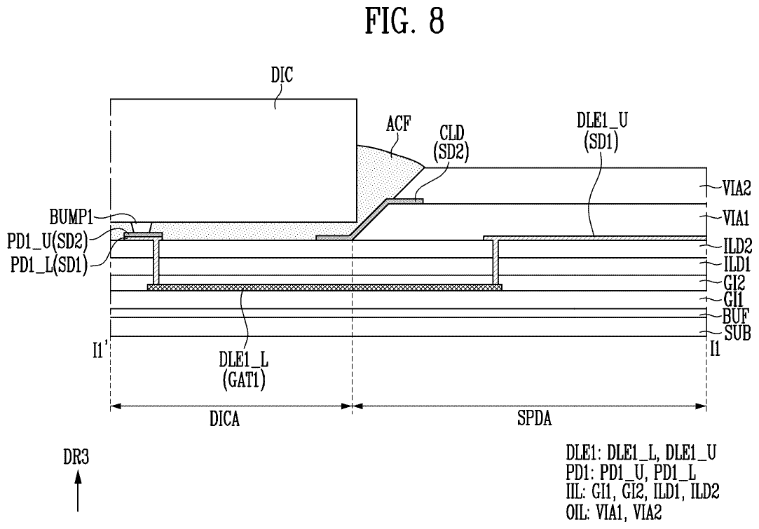

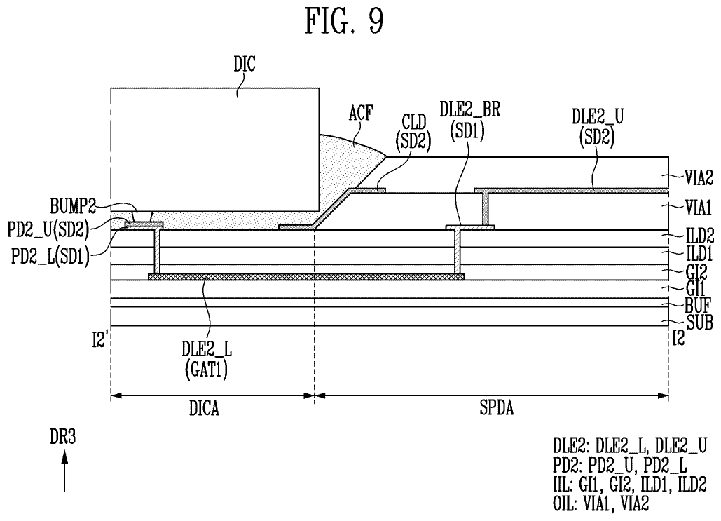

FIG. 8 is a cross-sectional view taken along line I1-I1′ in FIG. 7, according to an embodiment. FIG. 9 is a cross-sectional view taken along line I2-I2′ in FIG. 7, according to an embodiment.

In an embodiment and referring to FIGS. 8 and 9, the inorganic insulating layer array IIL may be disposed across the driving chip attachment area DICA and the wiring extension area SPDA. That is, the first gate insulating layer GI1, the second gate insulating layer GI2, the first interlayer insulating layer ILDI, and the second interlayer insulating layer ILD2 which are sequentially laminated along the third direction DR3 may be disposed across the driving chip attachment area DICA and the wiring extension area SPDA.

In an embodiment, the organic insulating layer array OIL may be disposed in the wiring extension area SPDA. The organic insulating layer array OIL may not be disposed in the driving chip attachment area DICA. That is the first via insulating layer VIA1 and the second via insulating layer VIA2 which are sequentially laminated along the third direction DR3 may be disposed only in the wiring extension area SPDA excluding the driving chip attachment area DICA.

In an embodiment and referring to FIG. 8, the first lower data extension wiring DLE1_L may be disposed in the driving chip attachment area DICA and the wiring extension area SPDA. In an embodiment, the first lower data extension wiring DLE1_L may be implemented as the first gate conductive layer GAT1. In this case, the first lower data extension wiring DLE1_L may be interposed between the first gate insulating layer GII and the second gate insulating layer GI2.

In an embodiment, the first data pad PD1 may be disposed in the driving chip attachment area DICA and may include a first lower data pad PD1_L and a first upper data pad PD1_U.

In an embodiment, the first lower data pad PD1_L may be implemented as the first SD conductive layer SD1 and the first upper data pad PD1_U may be implemented as the second SD conductive layer SD2. The first upper data pad PD1_U may cover at least an upper surface of the first lower data pad PD1_L. The first lower data pad PD1_L may be connected to the first lower data extension wiring DLE1_L through a through-hole penetrating the second gate insulating layer GI2, the first interlayer insulating layer ILD1, and the second interlayer insulating layer ILD2.

In an embodiment, the first upper data extension wiring DLE1_U may be disposed in the wiring extension area SPDA. In an embodiment, the first upper data extension wiring DLE1_U may be implemented as the first SD conductive layer SD1. In this case, the first upper data extension wiring DLE1_U may be interposed between the second interlayer insulating layer ILD2 and the first via insulating layer VIA1 and covered by the first via insulating layer VIA1. The first upper data extension wiring DLE1_U may be connected to the first lower data extension wiring DLE1_L through a through-hole penetrating the second gate insulating layer GI2, the first interlayer insulating layer ILD1, and the second interlayer insulating layer ILD2.

In an embodiment and referring to FIG. 9, the second lower data extension wiring DLE2_L may be disposed in the driving chip attachment area DICA and the wiring extension area SPDA. In an embodiment, the second lower data extension wiring DLE2_L may be implemented as the first gate conductive layer GAT1. In this case, the second lower data extension wiring DLE2_L may be interposed between the first gate insulating layer GI1 and the second gate insulating layer GI2.

In an embodiment, the second data pad PD2 may be disposed in the driving chip attachment area DICA and may include a second lower data pad PD2_L and a second upper data pad PD2_U.

In an embodiment, the second lower data pad PD2_L may be implemented as the first SD conductive layer SD1 and the second upper data pad PD2_U may be implemented as the second SD conductive layer SD2. The second upper data pad PD2_U may cover at least an upper surface of the second lower data pad PD2_L and the second lower data pad PD2_L may be connected to the second lower data extension wiring DLE2_L through a through-hole penetrating the second gate insulating layer GI2, the first interlayer insulating layer ILD1, and the second interlayer insulating layer ILD2.

In an embodiment, the data bridge electrode DLE2_BR may be disposed in the wiring extension area SPDA. In an embodiment, the data bridge electrode DLE2_BR may be implemented as the first SD conductive layer SD1. In this case, the data bridge electrode DLE2_BR may be interposed between the second interlayer insulating layer ILD2 and the first via insulating layer VIA1 and covered by the first via insulating layer VIA1. The data bridge electrode DLE2_BR may be connected to the second lower data extension wiring DLE2_L through a through-hole penetrating the second gate insulating layer GI2, the first interlayer insulating layer ILD1, and the second interlayer insulating layer ILD2.

In an embodiment, the second upper data extension wiring DLE2_U may be disposed in the wiring extension area SPDA. In an embodiment, the second upper data extension wiring DLE2_U may be implemented as the second SD conductive layer SD2. In this case, the second upper data extension wiring DLE2_U may be interposed between the first via insulating layer VIA1 and the second via insulating layer VIA2 and covered by the second via insulating layer VIA2. The second upper data extension wiring DLE2_U may be connected to the data bridge electrode DLE2_BR through a through-hole penetrating the first via insulating layer VIA1.

In an embodiment and referring to FIGS. 8 and 9, the data driving chip DIC may be disposed on the data pads PD1 and PD2 and may include a first bump BUMP1 and a second bump BUMP2. The first bump BUMP1 may protrude in a direction toward the first data pad PD1 and may be connected to the first data pad PD1. The second bump BUMP2 may protrude in a direction toward the second data pad PD2 and may be connected to the second data pad PD2.

In an embodiment, an adhesive layer ACF may be disposed between the data driving chip DIC and the inorganic insulating layer array IIL and may serve to secure the data driving chip DIC to be connected to the data pads PD1 and PD2 in a predetermined position. The adhesive layer ACF may be disposed to extend from the driving chip attachment area DICA to a portion of the wiring extension area SPDA to be adjacent to the driving chip attachment area DICA. In this case, in the wiring extension area SPDA, the adhesive layer ACF may be disposed on the organic insulating layer array OIL.

In an embodiment, the cladding electrode CLD may be disposed to cover the boundary between the organic insulating layer array OIL and the inorganic insulating layer array IIL between the data pads PD1 and PD2 and the upper data extension wirings DLE1_U and DLE2_U. That is, the cladding electrode CLD may be disposed to cover the boundary between the driving chip attachment area DICA and the wiring extension area SPDA.

In an embodiment, the cladding electrode CLD may be implemented as the second SD conductive layer SD2. In this case, the cladding electrode CLD may completely cover a side surface of the first via insulating layer VIA1 between the data pads PD1 and PD2 and the upper data connection wirings DLE1_U and DLE2_U. That is, between the data pads PD1 and PD2 and the upper data connection wirings DLE1_U and DLE2_U, the cladding electrode CLD may be interposed between the side surface of the first via insulating layer VIA1 and the adhesive layer ACF. In another embodiment, the cladding electrode CLD may expose a side surface of the second via insulating layer VIA2 between the data pads PD1 and PD2 and the upper data connection wirings DLE1_U and DLE2_U.

In an embodiment, at least a portion of the cladding electrode CLD may be interposed between the first via insulating layer VIA1 and the second via insulating layer VIA2. For example, the cladding electrode CLD may include a first portion covering the side surface of the first via insulating layer VIA1, and a second portion extending from the first portion and interposed between the first via insulating layer VIA1 and the second via insulating layer VIA2.

In an embodiment, at least a portion of the cladding electrode CLD may cover an upper surface of the inorganic insulating layer array IIL which is adjacent to the side surface of the first via insulating layer VIA1. For example, the cladding electrode CLD may include the first portion covering the side surface of the first via insulating layer VIA1, and a third portion extending from the first portion to cover the upper surface of the inorganic insulating layer array IIL.

In an embodiment, the cladding electrode CLD may serve to prevent direct contact between the first via insulating layer VIA1 and the adhesive layer ACF.

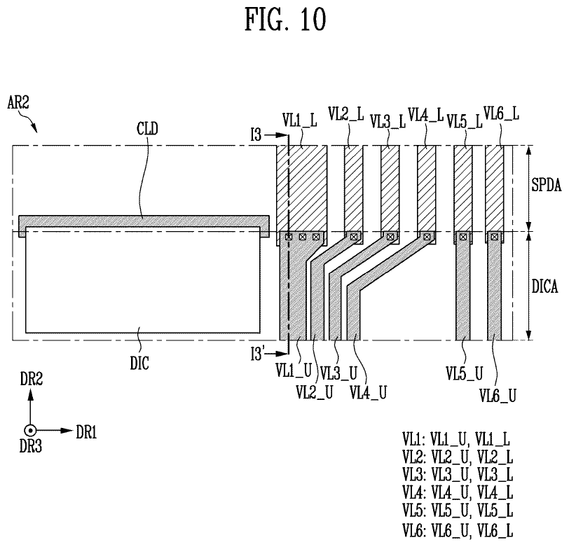

FIG. 10 is an enlarged plan view of an area AR2 in FIG. 4, according to an embodiment. Hereinafter, descriptions of contents that overlap with those described with reference to FIGS. 5 to 9 may be omitted. For a clear and concise description, the data extension wiring DLE described with reference to FIGS. 5 to 9 is omitted in FIG. 10.

In an embodiment and referring to FIG. 10, first to sixth voltage transmission wirings VL1, VL2, VL3, VLA, VL5, and VL6, respectively, may be disposed around the data driving chip DIC and the cladding electrode CLD. The voltage transmission wirings VL1, VL2, VL3, VL4, VL5, and VL6 may be spaced apart from each other.

In an embodiment, each of the voltage transmission wirings VL1, VL2, VL3, VLA, VL5, and VL6 may be connected to a corresponding voltage line among the first voltage line PL1, the second voltage line PL2, the first initialization voltage line VIL1, the second initialization voltage line VIL2, the reference voltage line VRL, and the bias voltage line VBL described with reference to FIG. 2. For example, the first voltage transmission wiring VL1 may be connected to the first voltage line PL1, and the first driving voltage ELVDD may be transmitted to the first voltage line PL1 through the first voltage transmission wiring VL1.

In an embodiment, the first voltage transmission wiring VL1 may include a first upper voltage transmission wiring VL1_U and a first lower voltage transmission wiring VL1_L. The first upper voltage transmission wiring VL1_U may be disposed in the driving chip attachment area DICA and the first lower voltage transmission wiring VL1_L may be disposed in the wiring extension area SPDA, and a portion thereof may be disposed in the driving chip attachment area DICA.

In an embodiment, the voltage transmission wirings VL2, VL3, VLA, VL5, and VL6 may be configured substantially similar to the first voltage transmission wiring VL1. For example, the voltage transmission wirings VL2, VL3, VL4, VL5, and VL6 may include upper voltage transmission wirings VL2_U, VL3_U, VL4_U, VL5_U, and VL6_U and lower voltage transmission wirings VL2_L, VL3_L, VL4_L, VL5_L, and VL6_L.

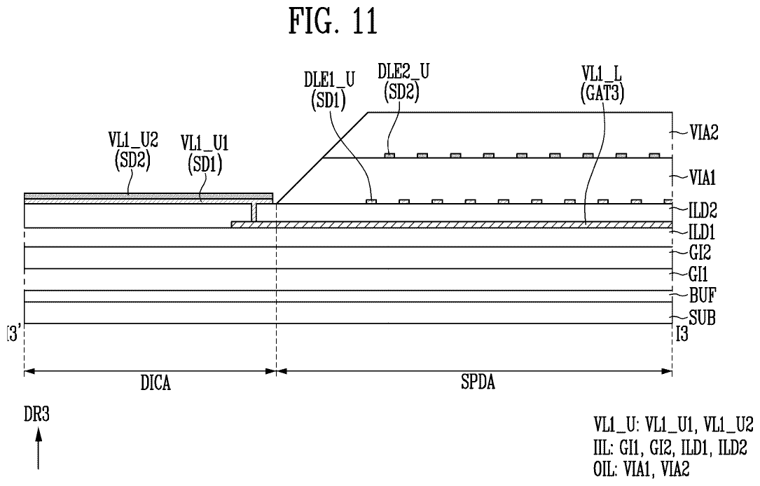

FIG. 11 is a cross-sectional view taken along line I3-I3′ in FIG. 10, according to an embodiment.

In an embodiment and referring to FIG. 11, the first lower voltage transmission wiring VL1_U may be disposed in the driving chip attachment area DICA and the wiring extension area SPDA. In an embodiment, the first lower voltage transmission wiring VL1_U may be implemented as the third gate conductive layer GAT3. In this case, the first lower voltage transmission wiring VL1_U may be interposed between the first interlayer insulating layer ILDI and the second interlayer insulating layer ILD2. In the wiring extension area SPDA, each of first upper data extension wirings DLE1_U interposed between the second interlayer insulating layer ILD2 and the first via insulating layer VIA1, and second upper data extension wirings DLE2_U interposed between the first via insulating layer VIA1 and the second via insulating layer VIA2 may be disposed to be insulated from and intersect with the first lower voltage transmission wiring VL1_U. In this way, the first voltage transmission wiring VL1 may be electrically insulated from the data extension wirings DLE.

In an embodiment, the first upper voltage transmission wiring VL1_U may be disposed in the driving chip attachment area DICA and may have a double-layer structure including a first layer VL1_U1 and a second layer VL1_U2.

In an embodiment, the first layer VL1_U1 may be implemented as the first SD conductive layer SD1, and the second layer VL1_U2 may be implemented as the second SD conductive layer SD2. The second layer VL1_U2 may cover at least an upper surface of the first layer VL1_U1. The first layer VL1_U1 may be connected to the first lower voltage transmission wiring VL1_U through a through-hole penetrating the second interlayer insulating layer ILD2.

In an embodiment, the voltage transmission wirings VL2, VL3, VLA, VL5, and VL6 may also be configured substantially similar to the first voltage transmission wiring VL1. For example, the upper voltage transmission wirings VL2_U, VL3_U, VL4_U, VL5_U, and VL6_U may have a double-layer structure implemented as the first SD conductive layer SD1 and the second SD conductive layer SD2, and the lower voltage transmission wirings VL2_L, VL3_L, VL4_L, VL5_L, and VL6_L may be implemented as the third gate conductive layer GAT3. The lower voltage transmission wirings VL2_L, VL3_L, VL4_L, VL5_L, and VL6_L may be disposed to be insulated from and intersect with the first upper data extension wirings DLE1_U and the second upper data extension wirings DLE2_U.

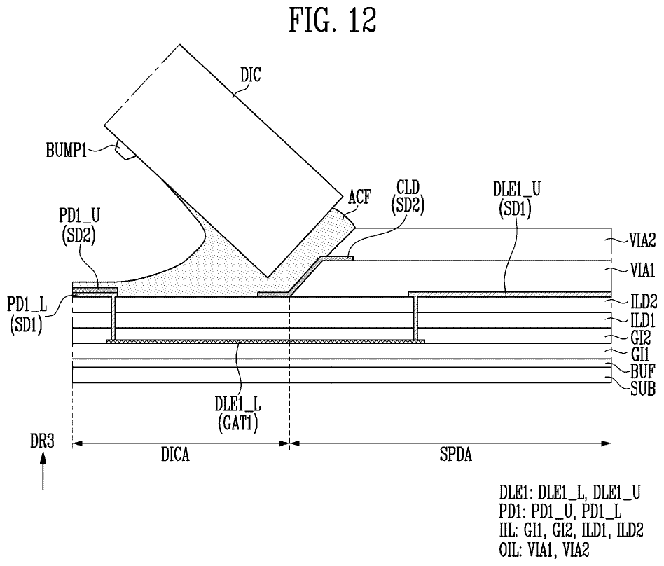

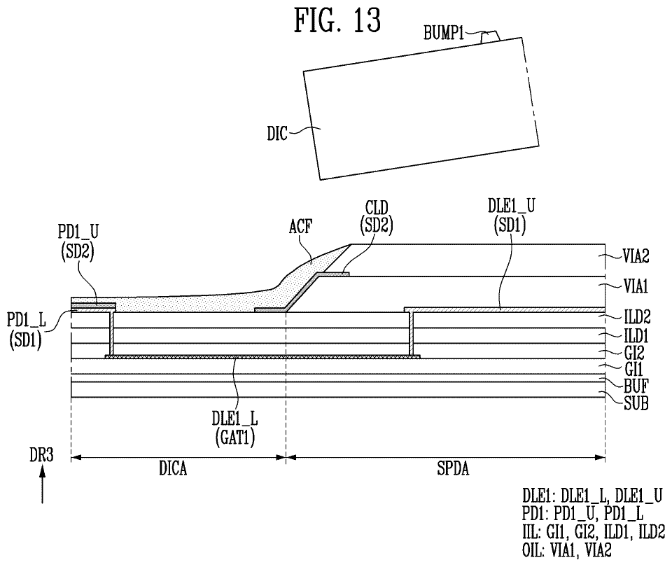

FIGS. 12 and 13 are diagrams for explaining a method for repairing a display device, according to an embodiment. Hereinafter, descriptions of the content that overlaps with those described with reference to FIGS. 5 to 11 may be omitted. For a clear and concise description, the description will be based on the cross-sectional shape shown in FIG. 8.

In an embodiment and referring to FIGS. 12 and 13, a defect may occur in the data driving chip DIC of the display device DD. In order for the display device DD to operate normally, it is necessary to remove the defective data driving chip DIC and then attach a normal data driving chip DIC.

To this end, a method for repairing the display device DD, according to an embodiment, may include removing the data driving chip DIC by applying an external force to the data driving chip DIC.

In an embodiment, a direction of the external force applied to the data driving chip DIC is not particularly limited, and for example, the external force may be applied in a direction toward the wiring extension area SPDA.

In an embodiment, since the data driving chip DIC is fixed by the adhesive layer ACF, when the external force is applied to the data driving chip DIC, at least a portion of the adhesive layer ACF attached to the data driving chip DIC may be removed together. Accordingly, components attached to the adhesive layer ACF may be peeled off (or removed) together while still attached to the adhesive layer ACF.

In an embodiment, unlike as shown in FIGS. 12 and 13, it may be assumed that the adhesive layer ACF is in direct contact with the first via insulating layer VIA1 (that is, a case where the cladding electrode CLD is omitted). In this case, by the external force applied to the data driving chip DIC, the adhesive layer ACF attached to the data driving chip DIC and the first via insulating layer VIA1 attached to the adhesive layer ACF may be removed together with the data driving chip DIC. Accordingly, as described with reference to FIG. 9, in the wiring extension area SPDA, the second upper data extension wiring DLE2_U disposed on the first via insulating layer VIA1 may be removed together.

In an embodiment, the cladding electrode CLD may serve to prevent physical contact between the adhesive layer ACF and the first via insulating layer VIA1. When the external force is applied to the data driving chip DIC, the adhesive layer ACF attached to the data driving chip DIC may be removed together. However, the cladding electrode CLD attached to the adhesive layer ACF may not be substantially removed. That is, the cladding electrode CLD may be relatively firmly fixed at the position where the cladding electrode CLD is disposed. The cladding electrode CLD may serve to prevent the first via insulating layer VIA1 from being peeled off. Accordingly, even if an external force is applied to the data driving chip DIC, the situation where the first via insulating layer VIA1 and the second upper data extension wiring DLE2_U disposed on the first via insulating layer VIA1 are removed together may not occur.

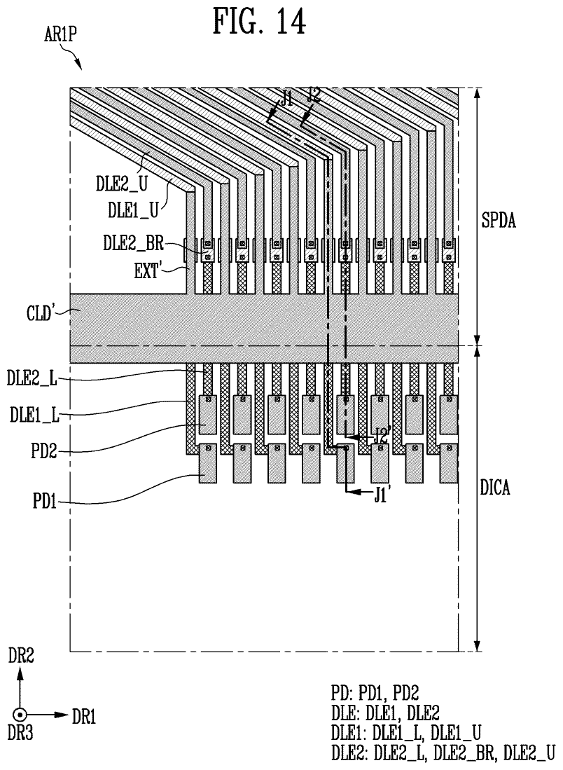

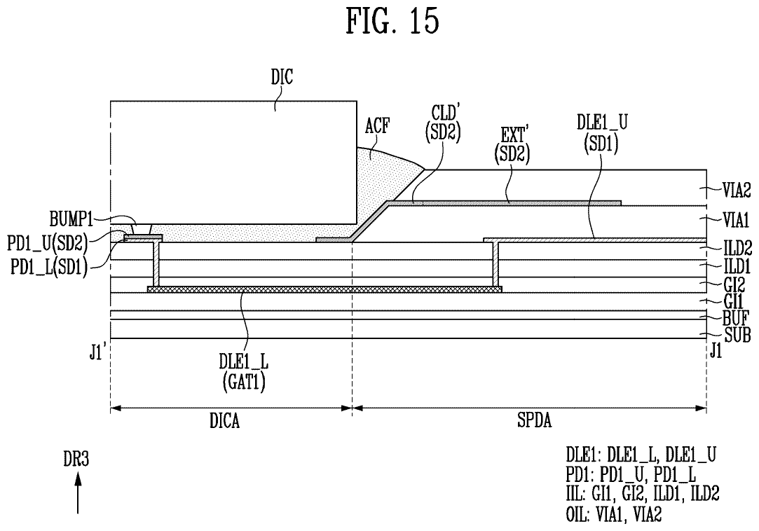

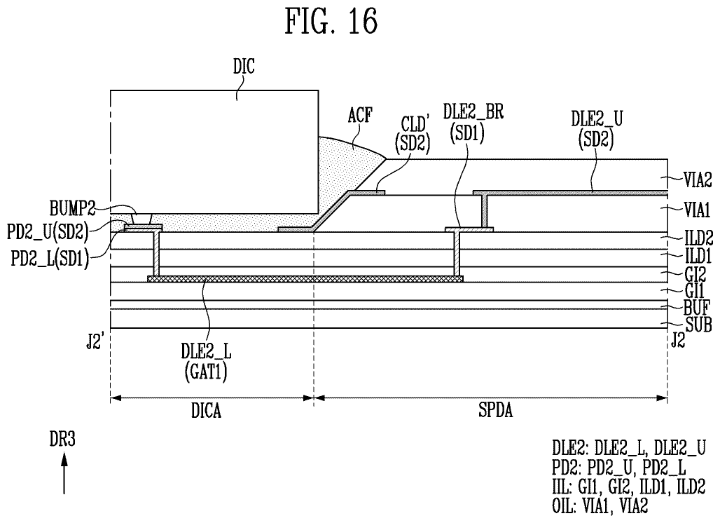

FIGS. 14 to 16 are diagrams for explaining one modified example of the cladding electrode included in the display panel of FIG. 4, according to an embodiment. Hereinafter, differences will be mainly explained in comparison with the embodiments described with reference to FIGS. 1 to 13, and parts that are omitted may be replaced with the contents described above.

In an embodiment and referring to FIGS. 14 to 16, a cladding electrode CLD′ may further include a protrusion EXT′ that overlaps the first upper data extension wiring DLE1_U when viewed on a plane. For example, the protrusion EXT′ may protrude in the second direction DR2 from the cladding electrode CLD′ when viewed on a plane. The first upper data extension wiring DLE1_U and the protrusion EXT′ may be provided in multiples, and protrusions EXT′ may be disposed to correspond one-to-one with the first upper data extension wirings DLE1_U.

In an embodiment, the protrusion EXT′ may be disposed on the same layer as the second upper data extension wiring DLE2_U. That is, the protrusion EXT′ may be implemented as the second SD conductive layer SD2.

In an embodiment, the protrusion EXT′ may be spaced apart from the second upper data extension wiring DLE2_U. That is, the protrusion EXT′ of the cladding electrode CLD may not be in physical contact with the second upper data extension wiring DLE2_U.

In an embodiment, the protrusion EXT′ may be interposed between the first via insulating layer VIA1 and the second via insulating layer VIA2 to provide a fixing force to the cladding electrode CLD′ so that the cladding electrode CLD′ is fixed at a predetermined position. Accordingly, even if the step of removing the data driving chip DIC is performed as described with reference to FIGS. 12 and 13, the cladding electrode CLD′ may not be substantially removed.

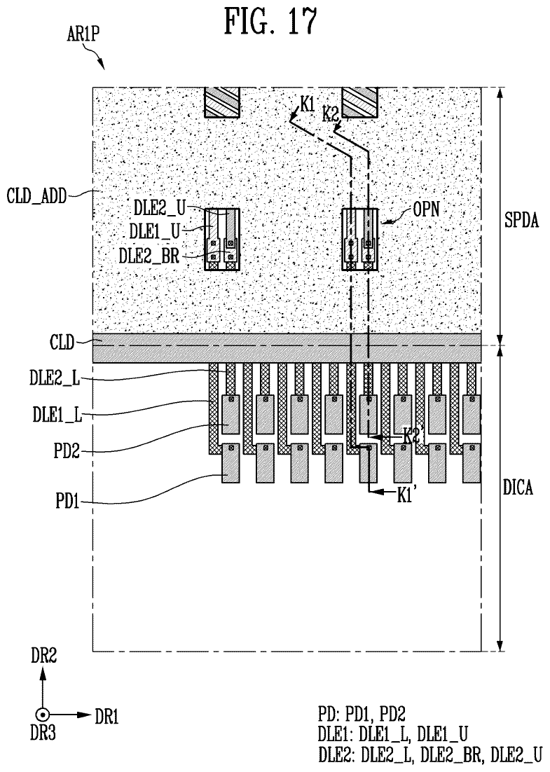

FIGS. 17 to 19 are diagrams for explaining another modified example of the cladding electrode included in the display panel of FIG. 4, according to an embodiment. Hereinafter, differences will be mainly explained in comparison with the embodiments described with reference to FIGS. 1 to 13, and parts that are omitted may be replaced with the contents described above.

In an embodiment and referring to FIGS. 17 to 19, an additional cladding electrode CLD_ADD may be further provided.

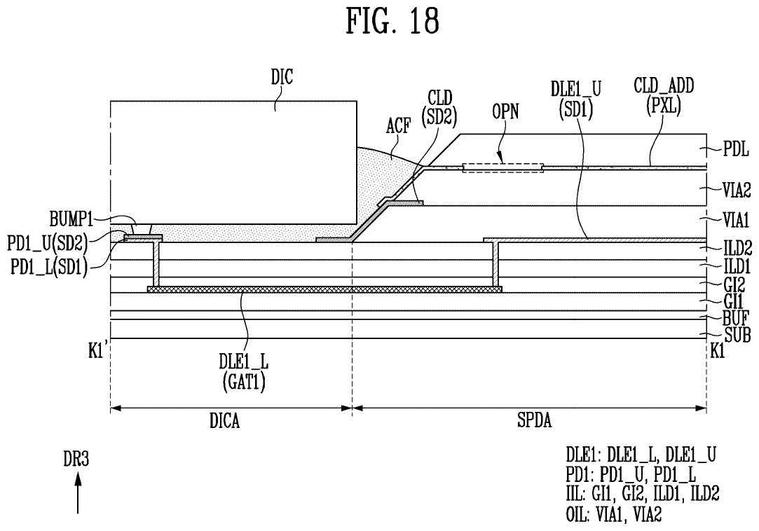

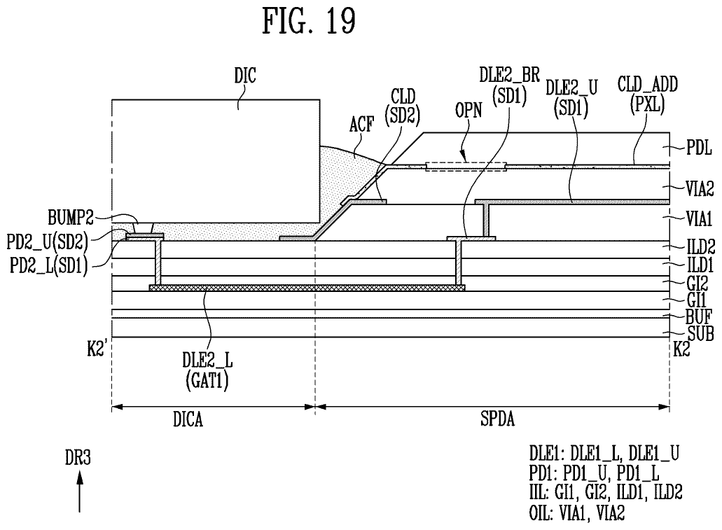

In an embodiment, the additional cladding electrode CLD_ADD may be implemented as the pixel electrode layer PXL. In this case, as shown in FIGS. 18 and 19, in the wiring extension area SPDA, the additional cladding electrode CLD_ADD may be interposed between the first via insulating layer VIA2 and the pixel defining layer PDL.

In an embodiment, the additional cladding electrode CLD_ADD may completely cover a side surface of the second via insulating layer VIA2 that is exposed and not covered by the cladding electrode CLD between the data pads PD1 and PD2 and the upper data extension wirings DLE1_U and DLE2_U. In this case, the additional cladding electrode CLD_ADD may be in contact with the cladding electrode CLD.

In an embodiment, the additional cladding electrode CLD_ADD may be interposed between the adhesive layer ACF and the second via insulating layer VIA2 to prevent the adhesive layer ACF from contacting the second via insulating layer VIA2. Accordingly, when the step of removing the data driving chip DIC is performed as described with reference to FIGS. 12 and 13, the additional cladding electrode CLD_ADD may serve to prevent the second via insulating layer VIA2 from being peeled off. Accordingly, the second via insulating layer VIA2 may not be substantially removed.

In an embodiment, the additional cladding electrode CLD_ADD may further include an opening OPN exposing a portion of an upper surface of the second via insulating layer VIA2. The opening OPN may serve to provide an outgassing passage for discharging gas generated in the organic insulating layer array OIL due to various factors (for example, heat generated by the operation of the display device DD).

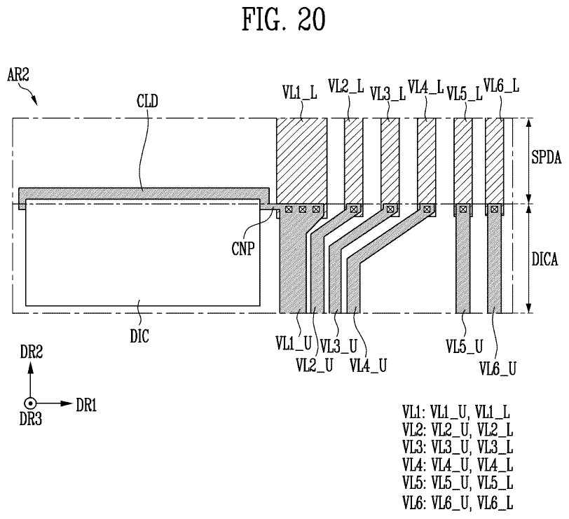

FIG. 20 is a plan view for explaining still another modified example of the cladding electrode included in the display panel of FIG. 4, according to an embodiment. Hereinafter, differences will be mainly explained in comparison with the embodiments described with reference to FIGS. 1 to 13, and parts that are omitted may be replaced with the contents described above.

In an embodiment and referring to FIG. 20, the cladding electrode CLD and the first voltage transmission wiring VL1 may be electrically connected to each other. For example, a connection member CNP electrically connecting the cladding electrode CLD and the first upper voltage transmission wiring VL1_U may be provided.

In an embodiment, a voltage applied to the first voltage transmission wiring VL1 may be applied to the cladding electrode CLD. In an embodiment, a level of the voltage applied to the first voltage transmission wiring VL1 may be a level between a high level and a low level of the data voltage Vdata applied to the lower data extension wirings DLE1_L and DLE2_L.

In an embodiment, the first driving voltage ELVDD may be applied to the first voltage transmission wiring VL1, where the first driving voltage ELVDD may have a voltage level range between about 4.5 V or more and about 4.7 V or less. The data voltage Vdata applied to the lower data extension wirings DLE1_L and DLE2_L may have a high level voltage of about 7 V and a low level voltage of about 3 V. However, the invention is not limited thereto. The voltage applied to the first voltage transmission wiring VL1 may be any one of various types of voltages having a level between the high level and the low level of the data voltage Vdata applied to the lower data extension wirings DLE1_L and DLE2_L.

In an embodiment and as described with reference to FIGS. 5 to 7, the cladding electrode CLD may overlap portions of the lower data extension wirings DLE1_L and DLE2_L. Accordingly, a situation may occur in which the data voltage Vdata is affected by the capacitance formed between the lower data extension wirings DLE1_L and DLE2_L and the cladding electrode CLD. In this case, when the voltage applied to the first voltage transmission wiring VL1 is set to satisfy the above-described description, the influence of the capacitance formed between the lower data extension wirings DLE1_L and DLE2_L and the cladding electrode CLD can be minimized.

In the display device, according to the invention, the cladding electrode may serve to protect the organic insulating layer array so that the organic insulating layer array is not peeled off. Accordingly, it is possible to prevent an upper data extension wiring disposed on any one of organic insulating layers constituting the organic insulating layer array from being removed due to the peeled off.

A display device according to an embodiment is applicable to various types of electronic devices. In an embodiment, an electronic device includes the above-described display device and may further include other modules or devices having additional functions in addition to the display device.

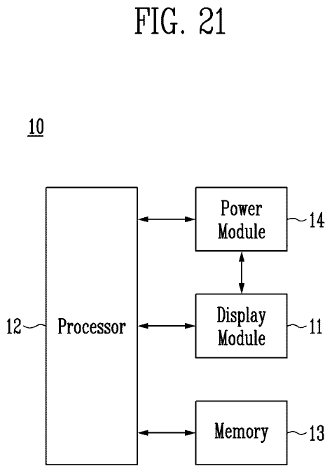

FIG. 21 is a block diagram of an electronic device according to an embodiment. Referring to FIG. 21, the electronic device 10 may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), and a controller. The memory 13 may store data and/or information used to operate the processor 12 or the display module 11. When the processor 12 executes an application stored in the memory 13, image data signals and/or input control signals may be transferred to the display module 11. The display module 11 may process the provided signals and output image information on a display screen.

The power module 14 may include a power supply module, such as a power adapter or a battery device, and a power conversion module. The power conversion module converts power supplied by the power supply module and generates power to operate the electronic device 10.

At least one of the above-described components of the electronic device 10 may be included in the display device according to embodiments as described above. In addition, in terms of functionality, some of the individual modules included in one module may be included in the display device and others may be provided separately from the display device. For example, the display module 11 is included in the display device, whereas the processor 12, the memory 13, and the power module 14 are not included in the display device and are instead provided separately in the electronic device 10.

FIG. 2 shows schematic views of various embodiments of an electronic device.

Referring to FIG. 2, various types of electronic devices to which embodiments of a display device are applied may include an electronic device to display images such as a smartphone 10_1a, a tablet PC 10_1b, a laptop computer 10_1c, a television (TV) 10_1d, and a desktop monitor 10_1e, a wearable electronic device including a display module such as smart glasses 10_2a, a head-mounted display (HMD) 10_2b, and a smart watch 10_2c, and an automotive electronic device 10_3 including a display module such as a center information display (CID) disposed at the instrument cluster, the center fascia, and the dashboard of a vehicle, and a room mirror display.

Although the invention has been described in detail with reference to embodiments, it will be understood by those skilled in the art that various modifications and changes can be made to the invention without departing from the spirit and scope of the invention. Moreover, example embodiments have been disclosed herein, and although specific terms are employed, they are used and are to be interpreted in a generic and descriptive sense only and not for purpose of limitation. In some instances, as would be apparent to one of ordinary skill in the art, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the invention. Thus, while various embodiments have been described above, those skilled in the art will appreciate that various modifications, additions and substitutions are possible, without departing from the scope and spirit of the invention.

What is claimed is:

1. A display device comprising:
an inorganic insulating layer array including a plurality of inorganic insulating layers sequentially laminated in a thickness direction;
a data pad disposed on the inorganic insulating layer array;
a data driving chip disposed on the data pad and connected to the data pad;
an adhesive layer disposed between the data driving chip and the inorganic insulating layer array;
a lower data extension wiring interposed between two adjacent inorganic insulating layers among the plurality of inorganic insulating layers included in the inorganic insulating layer array and connected to the data pad;
an upper data extension wiring disposed on the inorganic insulating layer array and connected to the lower data extension wiring;
an organic insulating layer array disposed on the inorganic insulating layer array, wherein the organic insulating layer array covers the upper data extension wiring, and includes a plurality of organic insulating layers sequentially laminated in the thickness direction; and
a cladding electrode covering a boundary located between the organic insulating layer array and the inorganic insulating layer array and located between the data pad and the upper data extension wiring.

2. The display device of claim 1, wherein the organic insulating layer array includes:
a first via insulating layer disposed on the inorganic insulating layer array; and
a second via insulating layer disposed on the first via insulating layer.

3. The display device of claim 2, wherein the cladding electrode disposed between the data pad and the upper data extension wiring covers a side surface of the first via insulating layer.

4. The display device of claim 3, wherein at least a portion of the cladding electrode is interposed between the first via insulating layer and the second via insulating layer.

5. The display device of claim 3, wherein at least a portion of the cladding electrode covers an upper surface of the inorganic insulating layer array disposed adjacent to the side surface of the first via insulating layer.

6. The display device of claim 3, wherein the cladding electrode disposed between the data pad and the upper data extension wiring is interposed between the side surface of the first via insulating layer and the adhesive layer.

7. The display device of claim 3, wherein the cladding electrode disposed between the data pad and the upper data extension wiring exposes a side surface of the second via insulating layer.

8. The display device of claim 7, further comprising:
an additional cladding electrode disposed on the second via insulating layer and completely covering the side surface of the second via insulating layer that is exposed and that is not covered by the cladding electrode between the data pad and the upper data extension wiring.

9. The display device of claim 8, wherein the additional cladding electrode is in contact with the cladding electrode.

10. The display device of claim 8, wherein the additional cladding electrode includes an opening exposing a portion of an upper surface of the second via insulating layer.

11. The display device of claim 2, wherein the data pad includes a first data pad, and a second data pad spaced apart from the first data pad,
wherein the lower data extension wiring includes a first lower data extension wiring connected to the first data pad and a second lower data extension wiring connected to the second data pad, and
wherein the upper data extension wiring includes a first upper data extension wiring connected to the first lower data extension wiring and a second upper data extension wiring connected to the second lower data extension wiring.

12. The display device of claim 11, wherein the first upper data extension wiring is interposed between the inorganic insulating layer array and the first via insulating layer, and
wherein the second upper data extension wiring is interposed between the first via insulating layer and the second via insulating layer.

13. The display device of claim 12, further comprising:
a data bridge electrode interposed between the inorganic insulating layer array and the first via insulating layer, and electrically contacting the second lower data extension wiring and the second upper data extension wiring.

14. The display device of claim 13, wherein the cladding electrode further includes a protrusion overlapping the first upper data extension wiring when viewed on a plane.

15. The display device of claim 14, wherein the protrusion is disposed on the same layer as the second upper data extension wiring.

16. The display device of claim 15, wherein the protrusion is spaced apart from the second upper data extension wiring.

17. The display device of claim 1, wherein the cladding electrode overlaps a portion of the lower data extension wiring when viewed on a plane.

18. The display device of claim 17, further comprising:
a voltage transmission wiring disposed on the inorganic insulating layer array and connected to the cladding electrode.

19. The display device of claim 18, wherein a level of a voltage applied to the voltage transmission wiring is a level between a high level and a low level of a data voltage applied to the lower data extension wiring.

20. A method for repairing a display device,
wherein the display device includes:
an inorganic insulating layer array including a plurality of inorganic insulating layers sequentially laminated in a thickness direction;
a data pad disposed on the inorganic insulating layer array;
a data driving chip disposed on the data pad and connected to the data pad;
an adhesive layer disposed between the data driving chip and the inorganic insulating layer array;
a lower data extension wiring interposed between two adjacent inorganic insulating layers among the plurality of inorganic insulating layers included in the inorganic insulating layer array and connected to the data pad;
an upper data extension wiring disposed on the inorganic insulating layer array and connected to the lower data extension wiring;
an organic insulating layer array disposed on the inorganic insulating layer array, covering the upper data extension wiring, and including a plurality of organic insulating layers sequentially laminated in the thickness direction; and
a cladding electrode covering a boundary located between the organic insulating layer array and the inorganic insulating layer array and located between the data pad and the upper data extension wiring, and
wherein the method includes:
removing the data driving chip by applying an external force to the data driving chip.

21. An electronic device comprising:
a display device, wherein the display device includes,
an inorganic insulating layer array including a plurality of inorganic insulating layers sequentially laminated in a thickness direction;
a data pad disposed on the inorganic insulating layer array;
a data driving chip disposed on the data pad and connected to the data pad;
an adhesive layer disposed between the data driving chip and the inorganic insulating layer array;
a lower data extension wiring interposed between two adjacent inorganic insulating layers among the plurality of inorganic insulating layers included in the inorganic insulating layer array and connected to the data pad;
an upper data extension wiring disposed on the inorganic insulating layer array and connected to the lower data extension wiring;
an organic insulating layer array disposed on the inorganic insulating layer array, wherein the organic insulating layer array covers the upper data extension wiring, and includes a plurality of organic insulating layers sequentially laminated in the thickness direction; and
a cladding electrode covering a boundary located between the organic insulating layer array and the inorganic insulating layer array and located between the data pad and the upper data extension wiring.
